(19) United States
(12) Patent Application Publication
(10) Pub. No.: US 2009/0129032 A1
(43) Pub. Date: May 21, 2009

(54) MODULAR SYSTEM CONTROLLED ACCORDING TO POWER REQUIREMENTS

(75) Inventors: Mirko Liedtke, Jena (DE); Gunter Moehler, Jena (DE)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: CARL ZEISS MICROIMAGING GMBH, Jena (DE)

(21) Appl. No.: 12/064,577

(22) PCT Filed: Jul. 7, 2006
(86) PCT No.: PCT/EP2006/006666

§ 371 Date: Feb. 22, 2008

(30) Foreign Application Priority Data
Aug. 23, 2005 (DE) 102005039886.3

(51) Int. Cl. H05K 5/00

(52) U.S. Cl. 361/730

(57) ABSTRACT

The invention relates to a modular system comprising a primary module, several individual modules that can be connected to said primary module and a power supply unit that is connected to the primary module and supplies the connected individual modules with a voltage. According to the invention, the system is equipped with a descriptor element for each individual module. The descriptor element is read by the primary module and encodes or displays the power requirements of the assigned individual module. The primary module reads the descriptor elements of the connected individual modules and uses said elements to determine the total power requirements of the modular system, or of all connected individual modules.

The invention relates to a modular system which comprises a main module and several individual modules connectable to said main module as well as a power supply unit supplying the system with a voltage. The invention further relates to a method for controlling the maximum power demand in such a modular system.

Modular systems are widely used in engineering because they can easily be adapted to a user's specific needs. An example of a modular system can be found in microscopy: Modern microscopes generally have a modular design. They comprise a main module to which various individual optical and/or electric modules, e.g. illuminating units, light sources, detectors or the like, can be attached. Another example of a modular system can be found in computer technology: Conventional PCs can be configured in various ways by installable or attachable modules, such as graphics cards, hard disks, and output devices, for example.

In modular systems, generally a single power supply unit supplies energy to the individual modules. It is then up to the person setting up the system to ensure that the maximum power the power supply unit can supply is sufficient to operate the system in the desired modular assembly. In systems which are generally operated in the same unchanged configuration, as in the case of computers, for example, monitoring whether the capacity of the power supply unit is sufficient is usually required only when assembling the system for the first time. The situation is different in the case of systems which are frequently modified by adding or removing individual modules, as is common, for example, in the case of microscopic systems. Accordingly, checking becomes more complicated the more frequently a modular system's configuration is modified.

It is sometimes not easy to check whether a power supply unit has sufficient capacity. If the individual modules are electrically supplied with energy by a supply rail, a voltage drop along the supply rail may lead to an insufficient supply of some individual modules. Depending on whether the individual module is coupled to the supply rail at the rail's beginning or end, the influence varies which a supply voltage drop during high power consumption has. Therefore, one approach taken is to over-dimension power supply units in order to avoid an untraceable functional failure of individual modules or even an overload of the power supply unit.

When designing the maximum power demand on the side of the power supply unit, it would be principally conceivable to have the current actually drawn measured by a shunt in the voltage supply, in which case the voltage drop at the shunt would be detected. Such a shunt could be located in a primary electric circuit or in a secondary electric circuit of the voltage supply. However, arranging said resistor in the primary circuit would yield a relatively unreliable result of measurement. In contrast thereto, a shunt in the secondary circuit would reduce the maximum admissible power of the individual modules or of the individual module. Therefore, these theoretically possible approaches have not been pursued in practice.

It is an object of the invention to improve a modular system of the above-mentioned type such that the maximum power demand of the system can be easily controlled. A further object of the invention is to provide a method of controlling the maximum power demand in a modular system of the above-mentioned type.

According to the invention, this object is achieved by a modular system which comprises a main module and several individual modules connectable thereto, as well as a power supply unit supplying a system with a voltage, wherein at least one descriptor element is provided for each individual module, which can be read by the main module, encodes or indicates the maximum power demand of the assigned individual module, and wherein the main module reads the descriptor elements of the connected individual modules and determines therefrom the total maximum power demand of all connected individual modules in order to prevent an overload of the power supply unit.

The object is further achieved by a method of controlling the maximum power demand of a modular system, which system comprises a main module and several individual modules connectable thereto as well as a power supply unit supplying the system with a voltage, wherein each individual module is provided with at least one descriptor element which can be read by the main module, encodes or indicates the maximum power demand of the assigned individual module, and wherein the descriptor elements of the connected individual modules are read and the total maximum power demand of all connected individual modules is determined therefrom.

Thus, according to the invention, each individual module to be connected to the system is provided with a descriptor element by which the main module can recognize the maximum load demand of the individual module. Overload situations are thus easily avoided. For this purpose, the main module reads the corresponding descriptor element, for example, prior to starting operation of the entire system or prior to starting operation of the individual module, in order to ensure that the capacity of the power supply unit is not exceeded by starting operation of the system/the individual module. Thus, the occurrence of an error can be avoided already prior to a fuse-breaking capacity limitation. This is achieved by the invention because the descriptor elements can be read independently of the actual operation of the individual modules. This is an essential difference to shunts which always indicate the current actually drawn only during actual operation of the individual module. Thus, the descriptor elements which can be polled independently of the operating condition allow a system diagnosis with respect to the maximum power demand independently of normal system operation.

Optionally, the main module can also poll or be polled, respectively, by a software tool to check what power reserves are still present, prior to contacting an individual module. The software tool determines the power balance of the system using the descriptors or the descriptor entries transferred to a table, respectively. Now, before connecting a further module to the existing system, it can be determined whether the module to be added can be supplied with power by the existing energy supply. For this purpose, the software tool can enable a corresponding module only if this is allowed by the energy supply. For example, such enablement can be effected in that the module is selectable by the software tool for installation only if sufficient power reserves exist. Alternatively, the additional individual module can be connected to the main module in the software simulation and the maximum power demand of the system can be determined in said simulation. This is a particularly precise check of the possibility of adding an individual module; if the latter is the case, the additional individual module can be connected without any problem.

If an individual module was added in some cases without determining its maximum power demand and if the power reserves were exceeded thereby, causing one of the individual modules to no longer be supplied with sufficient voltage, it would also be possible to determine the maximum power demand subsequently by evaluating the descriptor elements and to thus explain the insufficient supply of the individual module(s).

Thus, according to the invention, said descriptor elements can be used independently of the actual operation of the individual modules, which allows, in particular, a software simulation of the system with respect to the power requirements.

The maximum power demand, which is encoded or indicated for the assigned individual module by the descriptor element, may be obtained, for example, from design data or test results of the individual modules. The detailed realization of the descriptor module is possible in many variants all having in common that the descriptor elements are accessible to the main module independently of whatever operation of the individual modules.

A particularly simple construction uses electrical resistor elements as the descriptor elements. Each resistor element has one terminal which can be grounded, while the other terminal is connectable to the main module. If the main module switches the thus connected resistor elements in parallel and if the resistance value of each individual resistor element encodes the maximum power demand, the total maximum power demand of the system automatically results from the total resistance value of all resistor elements switched in parallel. Thus, a single-wire connection to the descriptor elements is achieved in an astonishingly simple manner. Using a resistance value for the resistor elements which has been computed, for example, by the equation 10,000/(power of the individual module), resistance values on the order of magnitude of 100 kΩ are obtained for usual module capacities. A parallel connection of such resistors in a conventional voltage dividing circuit having a reference resistance also of 100 kΩ at a supply voltage of 5 V results in a maximum voltage of measurement of 2.5 V, which is an optimal value, fully utilizing the converter range in conventional analog/digital converters.

Instead of encoding the power values by other, e.g. electrical quantities, a direct indication of the power value by memory elements can also be used. In doing so, memories can be polled in a wireless or wire-connected manner. An example of radio communication using a passive memory element is realized by the RFID chips known to the person skilled in the art. However, active systems provided with a source of energy are also possible. Reading of the descriptor elements is then effected by radio communication. These radio communication descriptors may preferably also be designed such that they can be activated, so that a communication can be effected only after activation of the descriptor. An activation (for example, enabling an antenna) which is effected automatically during installation/connection of the individual module is particularly preferred.

In the case of wire-bound communication between the main module and descriptor elements, a databus will be used, for example, via which data storage chips in the descriptor elements are read. For this purpose, it is preferred for the descriptor elements to respectively comprise one data storage chip each which can be connected to the main module via a data bus.

For wire-bound communication, one variant provides a contact mechanism of the descriptors, which effects connection of the descriptor elements prior to connecting the individual module, e.g. by means of known leading contacts. In this case, the individual module can be connected first only with respect to the descriptor element in order to check the maximum power demand. The individual module will be fully connected only if the power of the power supply unit is definitely sufficient.

It is essential for the approach according to the invention that each individual module has a descriptor element assigned to it. The descriptor elements may be provided as independent components, for example as plug-in elements which are plugged into corresponding slots of the main module. When installing a module, it is then only required to connect the corresponding descriptor element with the main module as well. Such a separate connection between the main module and the descriptor element can be dispensed with if each individual module incorporates at least one descriptor element which is automatically connected to the main module when connecting the individual module to the main module. This reduces the complexity of assembly when installing an individual module.

In many systems, the power supply unit provides different supply voltages, for example ±5 V, ±15V. If it is desired, in such cases, to keep the number of descriptor elements as low as possible, which may reduce the inconvenience of assembly, for example, in the case of descriptor elements not integrated in the individual modules, it is convenient if the descriptor element indicates a mixed value with respect to the maximum power demand for the different supply voltages used by the individual module. A more precise consideration of the maximum power demand is achieved if for each supply voltage used by the individual module or for each supply voltage provided by the power supply unit, respectively, one separate descriptor element per individual module is present, said descriptor element encoding or indicating the maximum power demand at the respective supply voltage.

Since the operation of the individual modules is separated from the determination of the maximum power demand in the concept according to the invention, an advanced error analysis is possible after breaking of a fuse. Overload of the power supply unit can then be checked by reading out the descriptor elements. Such overload is present if the total maximum power requirement exceeded an upper limit given by the power supply unit. However, if the power supply unit was able to satisfy the total power requirement, there must be a different error, for example a short circuit.

The system or the method, respectively, according to the invention makes it easy to upgrade the system while complying with the specifications of the power supply unit. Before upgrading a system or putting an upgraded system into operation, it is convenient to determine the total maximum power demand, e.g. by a software tool. If the total power requirement exceeds an upper limit given by the power supply unit, it is possible to either prevent operation of the entire system or at least operation of certain individual modules, e.g. of the individual module last added. The user can thus monitor the compliance with the restrictions set by the power supply unit. A system upgrade is particularly easy if the main module indicates the determined total power requirement. A comparison with the power parameters of the power supply unit allows, even before a system upgrade, for example before purchasing a further individual module, to determine whether the power supply unit is sufficient for such extension or whether an upgrade may have to be effected concerning the power supply unit. Therefore, before connecting or activating a further individual module, it is preferred to read its descriptor element and to check whether the power demand of this further individual module can be satisfied by the power supply unit in the system as well.

Of course, the features of the method described above or in the claims can also be realized by the main module, and vice versa. In order to realize the function of controlling the load demand, the main module may comprise a corresponding control device which may either be integrated in the main module or may be provided as an externally connected control device (for example, in the form of a computer).

The invention will be explained in more detail below, by way of example and with reference to the drawings, wherein

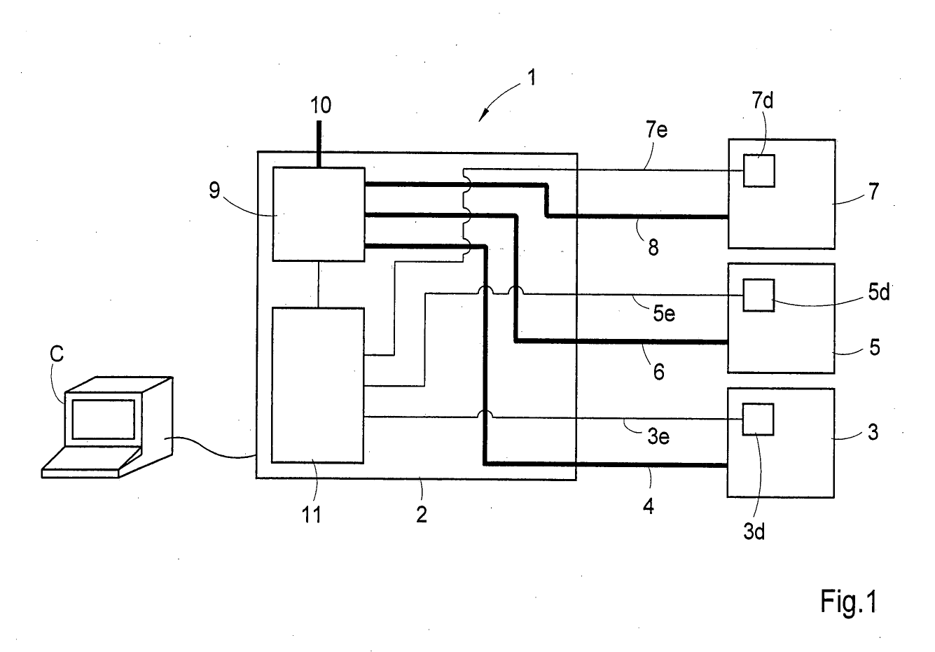

FIG. 1 shows a block diagram of a modular microscope system whose power demand is being monitored, and

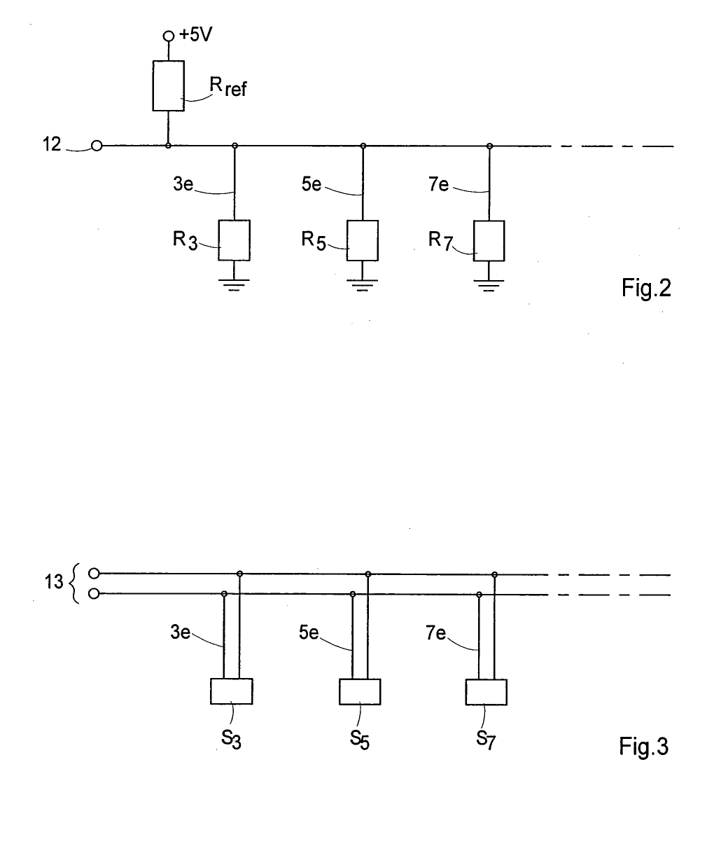

FIGS. 2 and 3 show electric circuit diagrams for realization of descriptor elements which are provided in the modules of the modular system of FIG. 1.

FIG. 1 shows a modular electric system exemplified by a modular microscope system 1. The system 1 comprises a main module 2, which is a basic microscope system in the exemplary embodiment to which various illumination and detection modules can be coupled. These modules are examples of the individual modules 3, 5 and 7 schematically shown in FIG. 1. Each individual module 3, 5 and 7 is supplied with energy via a current line 4, 6, 8 by a power supply unit 9 provided in the main module 2. The schematically indicated current lines 4, 6, 8 can also be provided as a distributor rail in a module port of the main module 2.

The power supply unit 9 provides different supply voltages to the individual modules 3, 5, 7, i.e. ±5 as well as ±15 V in the exemplary embodiment. The power supply unit 9 is in turn connected to an energy supply 10, e.g. an electric current network with 230 V a. c.

In order to detect the maximum power demand of the entire system 1 and, in particular, of the individual modules 3, 5 and 7, the main module 2 comprises a power detection circuit 11. Said circuit, which can also be accommodated in other control elements of the main module 2 or in a control unit (FIG. 1 schematically shows a computer C) externally connected to the main module 2, is connected to descriptors 3d, 5d or 7d via detection lines 31, 51 and 71, respectively, which descriptors are provided in the individual modules 3, 5 and 7.

As can be seen, each individual module 3, 5 and 7 has a descriptor. Each descriptor stores information concerning the maximum power demand of the assigned individual module. The power detection circuit 11 can thus easily determine, by reading the descriptors 3d, 5d and 7d, how big the maximum power demand of all connected individual modules 3, 5 and 7 is. Knowing the power of the power supply unit 9 (FIG. 1 schematically shows a connecting line for polling the maximum power), the power detection circuit 11 can thus determine, independently of the operation of the system 1, whether the power of the power supply unit 9 is sufficient.

The information laid down in the descriptor element 3d, 5d or 7d may be obtained, for example, by tests of the individual module 3, 5 or 7, in which the maximum current drawn by the individual module was determined.

Controlling the total maximum power demand of the system 1 or of all individual components 3, 5 and 7, i.e. of the system 1 without the main module 2, may be effected at any time. In particular, it can be done, when successively adding or attaching further individual modules, to trace or protocol the maximum power demand or the maximum current drawn at the supply voltages.

The power detection circuit 11 may indicate the total maximum power requirement or the still available residual capacity of the power supply unit 9 via a suitable output medium, e.g. the computer C. Thus, a user intending to operate an additional individual module requiring more power than the power supply unit 9 has left will either receive a warning concerning a required upgrade of the power supply unit or a suggestion which module could remain inoperative in order to keep the total maximum power demand of the operative system within the upper limit predetermined by the power supply unit 9. It is then possible to remove dispensable modules without requiring detailed knowledge of power values in the system 1.

Also, until the limit given, for example, by a safety fuse provided in the power supply unit 9 or in the energy supply 10, the user may be warned of an overload situation. The power detection circuit 11 may carry out a fault analysis even after the breaking of such a fuse and may indicate whether the fuse broke because of an overload of the power supply unit 9 or not. If there was no overload of the power supply unit 9, another error, for example a short circuit, must be present in the system 1. In a variant of the invention, a corresponding display is given.

The user may determine via the output unit, realized in the form of a computer C, for example, whether an upgrade of the power supply unit, a further power supply unit or a heavy-duty power supply unit is required. Upgrading of the power supply unit 9 may be effected, for example, by a further power supply unit, suitable capacitors, accumulators or batteries which increase the capacity of the power supply unit 9 for certain operating conditions or in general. Checking may also be effected via a data link (not shown in FIG. 1) directly by a maintenance service of the system manufacturer or by an external system administrator. Thus, the system according to FIG. 1 allows a remote fault analysis, so that any faults in the installed system can be quickly recognized and counter-measures can be initiated.

In a variant of the system 1 of FIG. 1, the power supply unit 9 provides various supply voltages, e.g. ±5 V and ±15 V. The descriptors 3d, 5d and 7d then encode an average maximum power demand (averaged over all voltages). In an alternative embodiment, a separate descriptor element (not shown in FIG. 1) is provided for each voltage of each individual module.

FIG. 1 shows the descriptors as parts of the individual modules 3, 5 and 7. In a constructive variant of the system 1, the descriptors are provided separately and independently of the individual modules. For example, the main module 2 has suitable slots into which the descriptors of the connected individual modules are plugged.

FIG. 2 shows a possible construction of the descriptors 3d, 5d and 7d. They are respectively realized as resistors R3, R5 and R7. One terminal of each resistor is grounded, the other is connected to the respective detection line 3I, 5I and 7I. The power detection circuit 11 then switches all resistors R3, R5 and R7 in parallel in a voltage-dividing circuit, as shown in FIG. 2. The voltage divider consists of a reference resistor Rref, which is located between a supply voltage of +5 V, in this case, and the connecting line between the detection lines 31, 51 and 71 to the resistors R3, R5 and R7. This connection simultaneously provides a measurement terminal 12, at which the power detection circuit 11 detects the appearing voltage value. Thus, the voltage at the measurement terminal 12 exactly indicates the total maximum power requirement of the individual modules 3, 5 and 7 (encoded in the form of resistors R3, R5 and R7).

If the individual resistors R3, R5 and R7 are on the same order of magnitude as the reference resistor Rref, as already explained above, a measurement voltage of ≦2.5 V is present at the measurement terminal 12. This is usually the maximum voltage value of an A/D converter.

In the variant where a separate descriptor is used for each voltage value, there is a voltage-dividing chain according to FIG. 2 for each voltage value. The respective measurement terminals then give the maximum power requirement at the respective supply voltage.

FIG. 3 shows an alternative embodiment of the descriptor elements which are realized as memory elements S3, S5 and S7. These memory elements contain information on the maximum power requirement of the assigned individual modules 3, 5 or 7. According to one embodiment, said information is also split up according to different supply voltages. The memory elements S3, S5 and S7 are connected to a bus terminal 13 via a system of lines, so that the power detection circuit 11 detects the power requirement of every single individual module 3, 5, 7 and also the total maximum power demand—even individually for the individual supply voltages, depending on the embodiment—by simply polling the memory elements via the bus, which may be embodied, for example, according to the USB system or the CAN bus.

Even single-wire, double-wire or multiple-wire bus systems are possible. Thus, by evaluating the descriptor elements 3d, 5d, 7d, an optimal usage at the individual voltages (at which the individual modules may have different demands) can be achieved.

1-9. (canceled)

10. A modular system, comprising a main module and several individual modules connectable to said main module as well as a power supply unit supplying the system with a voltage, wherein for each individual module at least one descriptor element is provided, which can be read by the main module and encodes or indicates the maximum power demand of the assigned individual module, and wherein the main module reads the descriptor elements of the connected individual modules and thereby determines the total maximum power demand of all connected individual modules in order to prevent an overload of the power supply unit.

11. The system as claimed in claim 10, wherein the descriptor elements each comprise at least one electric resistor element, which is grounded on the one hand and is connectable to the main module on the other hand and whose resistance value encodes the maximum power demand of the individual module, with the main module determining the total resistance value of all resistor elements connected in parallel.

12. The system as claimed in claim 10, wherein the descriptor elements each comprise a data storage chip which is connectable to the main module via a databus.

13. The system as claimed in claim 10, wherein each individual module incorporates at least one descriptor element which is automatically connected to the main module when connecting the individual module to the main module.

14. The system as claimed in claim 11, wherein each individual module incorporates at least one descriptor element which is automatically connected to the main module when connecting the individual module to the main module.

15. The system as claimed in claim 12, wherein each individual module incorporates at least one descriptor element which is automatically connected to the main module when connecting the individual module to the main module.

16. The system as claimed in claim 10, wherein the power supply unit provides several supply voltages to the individual modules, and for each individual module one descriptor element is provided for each supply voltage, encoding or indicating the maximum power demand at said supply voltage.

17. The system as claimed in claim 11, wherein the power supply unit provides several supply voltages to the individual modules, and for each individual module one descriptor element is provided for each supply voltage, encoding or indicating the maximum power demand at said supply voltage.

18. The system as claimed in claim 12, wherein the power supply unit provides several supply voltages to the individual modules, and for each individual module one descriptor element is provided for each supply voltage, encoding or indicating the maximum power demand at said supply voltage.

19. The system as claimed in claim 13, wherein the power supply unit provides several supply voltages to the individual modules, and for each individual module one descriptor element is provided for each supply voltage, encoding or indicating the maximum power demand at said supply voltage.

20. A method for controlling the maximum power demand of a modular system, said modular system comprising a main module and several individual modules connectable thereto as well as a power supply unit supplying the system with a voltage, wherein for each individual module at least one descriptor element is provided, which can be read out by the main module and encodes or indicates the maximum power demand of the assigned individual module, and wherein the descriptor elements of the connected individual modules are read and the total maximum power demand of all connected individual modules is determined.

21. The method as claimed in claim 20, wherein the total maximum power demand of the modular system is determined before activating all connected individual modules and, in the case of a total power demand exceeding an upper limit given by the power supply unit, simultaneous operation of all individual modules or operation of specific individual modules is prevented.

22. The method as claimed in claim 20, wherein, after breaking of an electric safety fuse, the total maximum power requirement of the modular system is compared with an upper limit given by the power supply unit in order to be able to distinguish a short circuit in the system from an overload of the power supply unit.

23. The method as claimed in claim 21, wherein, after breaking of an electric safety fuse, the total maximum power requirement of the modular system is compared with an upper limit given by the power supply unit in order to be able to distinguish a short circuit in the system from an overload of the power supply unit.

24. The method as claimed in claim 20, wherein prior to connecting or activating a further individual module the descriptor element of the latter is read, and it is checked whether in the system the maximum power demand of this further individual module can also be satisfied by the power supply unit.

25. The method as claimed in claim 21, wherein prior to connecting or activating a further individual module the descriptor element of the latter is read, and it is checked whether in the system the maximum power demand of this further individual module can also be satisfied by the power supply unit.

26. The method as claimed in claim 22, wherein prior to connecting or activating a further individual module the descriptor element of the latter is read, and it is checked whether in the system the maximum power demand of this further individual module can also be satisfied by the power supply unit.
